(19) United States
(12) Patent Application Publication
(10) Pub. No.: US 2008/0054447 A1
(43) Pub. Date: Mar. 6, 2008

(54) CHIP PACKAGE AND DIGITAL CAMERA MODULE USING SAME

(75) Inventors: CHIH-CHENG WU, Chu-Nan (TW); CHANG-KUO YANG, Chu-Nan (TW); MING LEE, Chu-Nan (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: ALTUS TECHNOLOGY INC., Chu-Nan (TW)

(21) Appl. No.: 11/616,838

(22) Filed: Dec. 27, 2006

(30) Foreign Application Priority Data
Aug. 23, 2006 (CN) 200610062246.7

(51) Int. Cl. H01L 23/12

(52) U.S. Cl. 257/704

(57) ABSTRACT

A digital camera module (200) includes a chip package (20) and a lens module (50) mounted to the chip package. The package includes a carrier (21), a chip (23), a plurality of wires (24), a supporting member (25), an adhesive (26), and a cover (28). The carrier has a top surface (211), and a plurality of top contacts (215) arranged on the top surface. The chip is mounted to the top surface of the carrier, and includes an active area (231) and a plurality of pads (233). The wires electrically respectively connect one of the pads to a corresponding top contact. The adhesive is applied to a peripheral circumference of the top surface of the chip. The cover is adhered to the adhesive, and closes the active area of the chip. The supporting member is disposed between the carrier and the cover to support the cover.

### CROSS-REFERENCE TO RELATED APPLICATIONS

This application is related to two co-pending U.S. patent applications (Attorney Docket No. US11425; and US11426), respectively entitled “CHIP PACKAGE AND DIGITAL CAMERA MODULE USING SAME” and “CHIP PACKAGE AND DIGITAL CAMERA MODULE USING SAME”, by Chih-Cheng Wu et al. Such applications have the same assignee as the present application and have been concurrently filed herewith. The above-identified applications are incorporated herein by reference.

### BACKGROUND

1. Technical Field

The present invention generally relates to integrated circuit chip packages and digital camera modules using the package and, more particularly, to an image sensor chip package and a digital camera module using the package.

2. Description of the Related Art

Generally, digital cameras are image-recording media capable of photographing a plurality of still images without using film. Such a digital camera typically uses an image pickup device, which is a kind of semiconductor device, such as a charge coupled device (CCD) or complementary metal oxide semiconductor (CMOS). In the digital camera, an object image formed on the image pickup device through a lens is converted into an electrical signal by the image pickup device, and the electrical signal is stored as a digital signal, e.g., in a mobile phone or personal digital assistant (PDA), in which the digital camera is mounted, or in a “stand-alone” digital still or video camera unit. In order to protect the image pickup device from contamination or pollution (i.e. from dust or water vapor), the image pickup device is generally sealed in a structural package.

FIG. 1 (related art) shows a typical digital camera module 100 using a chip package 10. The digital camera module includes the chip package 10, a second adhesive 12, and a lens module 14. The chip package 10 is constructed to include a base 101, a chip 105, a plurality of wires 106, a first adhesive 107, and a cover 108. The base 101 includes a board portion 102, a frame portion 103 upwardly extending from a periphery of the base board 101, and a cavity 103 cooperatively formed by the board portion 102 and the frame portion 103. A plurality of top contacts 1021 and bottom contacts 1022 are respectively mounted on two sides of the board portion 102, and the top contacts 1021 are contained in the cavity 103. Each top contacts 1021 is electrically connected to a corresponding bottom contact 1022 via a respective interconnecting device (not shown) which could be plated through holes or conductive leads. The chip 105 includes an active area 1051 and a number of pads 1052 formed thereon. The chip 105 is received in the cavity 103 and adhered to the board portion 102 of the base 10. The wires 106 are provided to electrically connect the pads 1052 of the chip 105 and the top contacts 1021 of the base 10. The cover 108 is mounted to the top of the frame portion 103 via the first adhesive 107, which is applied on the top of the frame portion 103. The second adhesive 12 is applied to a periphery of a top surface of the cover 108. The lens module 14 is attached to the cover 108 via the second adhesive 12.

In the aforesaid chip package 10 of the digital camera module 100, the cavity 103 of the base 10 must contain both of the top contacts 1021 and the chip 105 therein, and there must define a space between an outer periphery of the chip 105 and an inner periphery of the frame portion 103 of the base 10 for allowing movement of a wire bonding tool, which accordingly results in a relative large volume of the chip package 10 relative to the volume of the chip 105.

Additionally, the relative large volume of the chip package 10 results in more dust-particles adhering to the cover 108, the board portion 102 and the frame portion 103 of the base 101. Thus, more dust-particles will drop onto the chip 105. The dust-particles may obscure the optical path and produce errors in the image sensing process. Accordingly, the quality and/or reliability of the chip package 10 may be adversely affected.

Furthermore, it is difficult to ensure that an optical axis of the lens module 14 is precisely aligned with a center of the active area 1051 of the chip 105 when mounting the lens module 15 onto the frame portion 103. In cases where the optical axis of the lens module 15 is somehow displaced from the center of the chip 105, a distorted image will be projected onto the chip 105, which may accordingly adversely affect the quality of images formed by the digital camera module 100.

Therefore, an improved chip package and an improved digital camera module are desired in order to overcome the above-described shortcomings.

### SUMMARY

In one aspect, a chip package is provided. The chip package includes a carrier, a chip, a plurality of wires, a supporting member, an adhesive, and a cover. The carrier has a top surface, and a plurality of top contacts arranged on the top surface. The chip is mounted to the top surface of the carrier, and includes an active area and a plurality of pads disposed on a top surface thereof. The wires electrically respectively connect one of the pads to a corresponding top contact of the carrier. The adhesive is applied to a peripheral circumference of the top surface of the chip, around the active area. The cover is adhered to the adhesive, the cover and the adhesive cooperatively close the active area of the chip. The supporting member is disposed between the top surface of the carrier and the cover to support the cover.

In another aspect, a digital camera module is provided. A digital camera module includes a chip package and a lens module mounted to the chip package. The chip package includes a carrier, a chip, a plurality of wires, a supporting member, an adhesive, and a cover. The carrier has a top surface, and a plurality of top contacts arranged on the top surface. The chip is mounted to the top surface of the carrier, and includes an active area and a plurality of pads disposed on a top surface thereof. The wires electrically respectively connect one of the pads to a corresponding top contact of the carrier. The adhesive is applied to a peripheral circumference of the top surface of the chip, around the active area. The cover is adhered to the adhesive, the cover and the adhesive cooperatively close the active area of the chip. The supporting member is disposed between the top surface of the carrier and the cover to support the cover.

Other advantages and novel features will become more apparent from the following detailed description when taken in conjunction with the accompanying drawings.

### BRIEF DESCRIPTION OF THE DRAWINGS

Many aspects of the present chip package and digital camera module using the package can be better understood with reference to the following drawings. The components in the drawings are not necessarily drawn to scale, the emphasis instead being placed upon clearly illustrating the principles of the chip package and digital camera module using the package. Moreover, in the drawings, like reference numerals designate corresponding parts throughout the several views.

FIG. 1 is a cross-sectional view of a typical digital camera module;

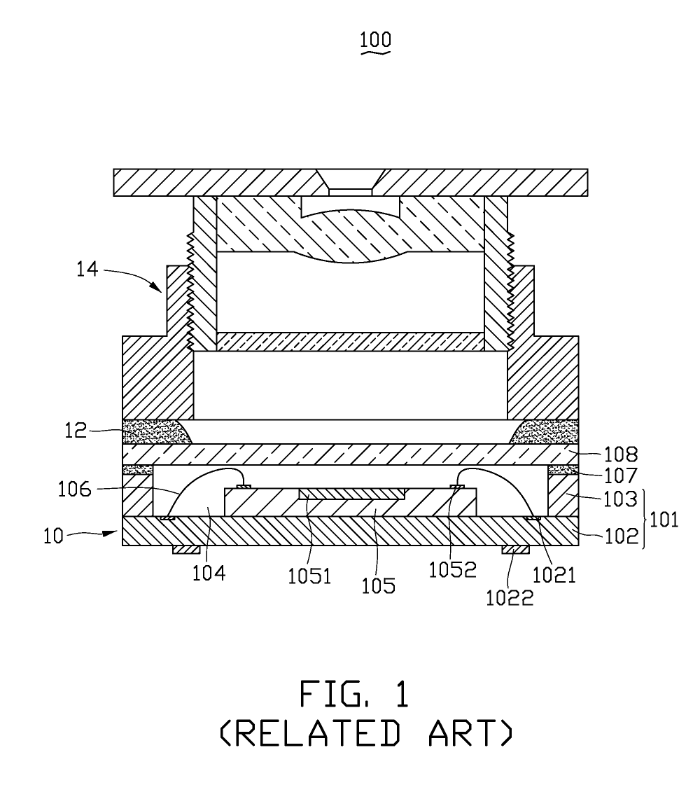

FIG. 2 is a schematic, cross-sectional view of a digital camera module having a chip package, according to a preferred embodiment of the present invention; and

FIG. 3 is a top view of the chip package shown in FIG. 2, but not showing the cover.

### DETAILED DESCRIPTION OF THE PREFERRED EMBODIMENT

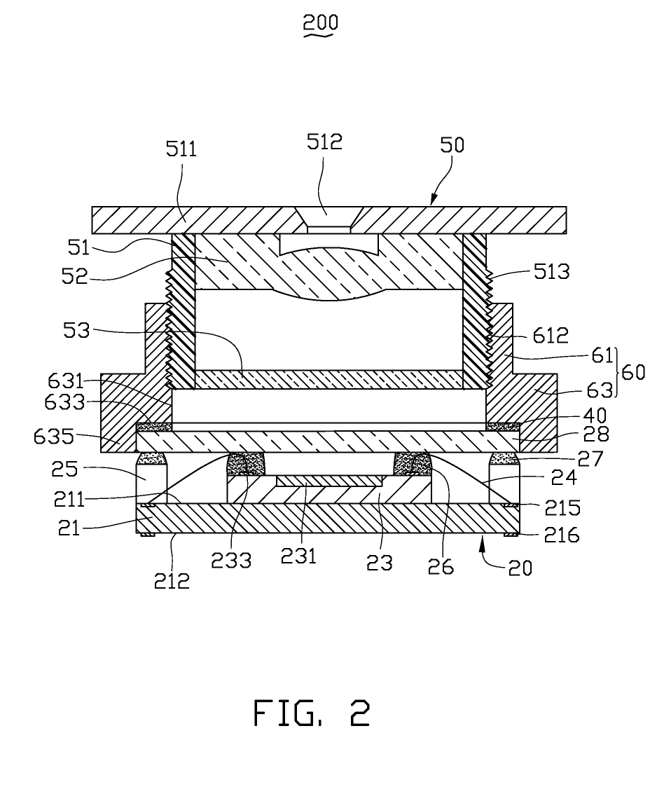

Referring to FIG. 2, a digital camera module 200 having a chip package 20 according to a preferred embodiment of the present invention is shown. The digital camera module 20 includes the chip package 20, a third adhesive 40, a lens module 50, and a holder 60.

The chip package 20 includes a carrier 21, a chip 23, a plurality of wires 24, a supporting member 25, a first adhesive 26, a second adhesive 27, and a cover 28.

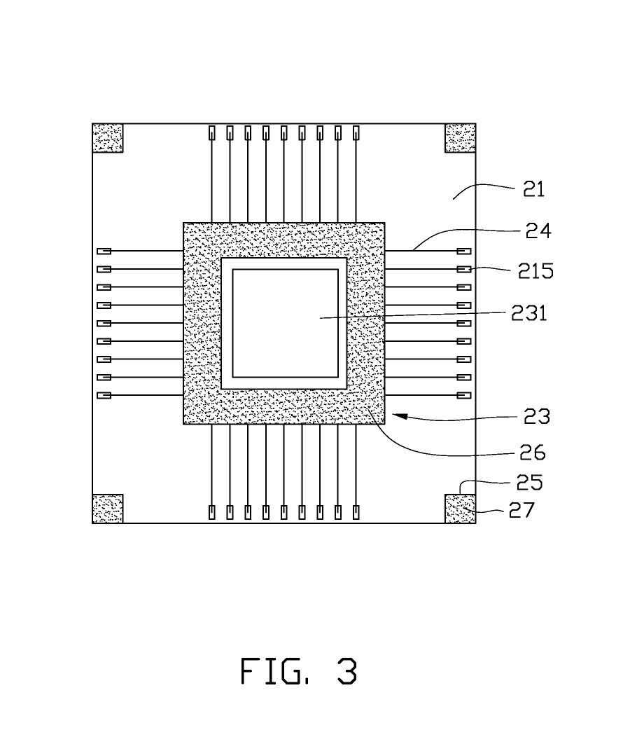

Referring to FIGS. 2 and 3, the carrier 21 has an approximately planar top surface 211, a bottom surface 212 positioned opposite to the top surface 212, a plurality of top contacts 215 arranged on the top surface 211, and a plurality of bottom contacts 216 disposed on the bottom surface 212. Each top contact 215 electrically connects with a corresponding bottom contact 216 via a respective interconnecting device (not shown). The top and bottom contacts 215, 216 are both configured for electrically connecting with other electronic components, for example the top contacts 215 can be used to electrically connect to a chip and the bottom contacts 216 can be used to electrically connect with a printed circuit board (PCB), thereby transmitting signals from the chip to the PCB via the interconnecting device. The interconnecting device can be plated through holes or conductive leads.

The chip 23 can be, for example a complementary metal-oxide-semiconductor transistor (CMOS) image sensor, or a charge coupled device (CCD) image sensor, and is mounted to the top surface 211 of the carrier 21. A top surface of the chip 23 is arranged with an active area 231 (e.g., a photo-registering zone) and a number of pads 233 arranged around the active area 231. The pads 233 are configured for electrically connecting with other electronic components to transmit electrical signal from the chip 23 to other electronic components.

The wires 24 can be made of a conductive material with good electric conductivity, such as gold or aluminum alloy. One end of each wire 24 is connected/joined with a respective pad 233 of the chip 23, and the other end of the wire 24 is connected/joined with a respective top contact 215 of the carrier 21.

The supporting member 25 is adapted for spacing the cover 28 over the top surface of the chip 23. The supporting member 25 includes four columns which are respectively disposed at a corner of the top surface 211 of the carrier 21. The supporting member 25 can be fixed to the carrier 21 via mount members such as adhesives or screws.

The first adhesive 26 is applied to the top surface of the chip 23 along a peripheral circumference, and covers connecting areas/joints where the wires 23 connect/join with the pads 233. The first adhesive 26 can be further applied to the wires 23 in a manner so as to cover the whole of each wire 23 in order to protect wires 23 from damage due to external force.

The second adhesive 27 is applied to the top of the supporting member 26.

The cover 28 is transparent plate member made of glass or plastic so as to permit light transmit therethrough, and is disposed over the top surface of the chip 23. The cover 28 has a dimension approximately equal to that of the carrier 21. The cover 28 is placed over the active area 231 of the chip 23, and is adhered to the top surface of the chip 23 via the first adhesive 26, and is adhered to the supporting member 25 via the second adhesive 27 so as to be supported by the supporting member 25 thereby being spaced a certain distance from the top surface of the chip 23 to avoid damaging/ruining the wires 24. The cover 28 and the first adhesive 26 cooperatively define a sealing space to close the active area 231 of the chip 23.

The third adhesive 40 is applied to a periphery of a top surface of the cover 28.

The lens module 50 includes a barrel 51, at least one lens 52 and a filter 53. The barrel 51 is a hollow cylinder for receiving the at least one lens 52 and the filter 53 therein, and has an external thread 513 formed on an external surface thereof. One end of the barrel 51 is covered by a plate 511 which has a transparent region 512 formed in a central portion thereof so that light can be transmitted therethrough.

The holder 60 includes a cylinder portion 61 configured (i.e., structured and arranged) for receiving the lens module 50, a seat portion 63 from which the cylinder portion 61 projects, and a through hole defined by the respective interiors of the cylinder portion 61 and the seat portion 63 and penetrating therethrough. The cylinder portion 61 has an internal thread 612 formed thereon for mating with the external thread 513 of the lens module 50. The seat portion 63 has an inner circumferential wall 631, an end surface 633 positioned opposite to the cylinder portion 61, and a frame section 635 axially protruding from a periphery of the end surface 633. The inner circumferential wall 631 has a dimension smaller than that of the peripheral circumference of the cover 28. The frame section 633 has an inner periphery which has a dimension approximately equal to that of the peripheral circumference of the cover 28.

The seat portion 63 of the holder 60 is mounted to the chip package 20, wherein the end surface 633 of seat portion 63 of the holder 60 is adhered to the cover 28 via the third adhesive 40, and an inner wall of the frame section 635 tightly contacts with a peripheral sidewall of the cover 28. The cylinder portion 61 receives the lens module 50 therein, with the internal thread 612 of the cylinder portion 61 engaging with the internal thread 513 of the barrel 51. The at least one lens 52 faces toward the active area 231 of the chip 23 to form an image thereon.

It is to be understood that the lens module 50 can be omitted so long as at least one lens is received in the cylinder portion 61 of the holder 60 to form a focused image on the active area 231 of the chip 23.

Additionally, the columns of the supporting member 25 each can have an end integrally formed with a respect corner of the top surface 211 of the carrier 21.

Alternatively, the columns of the supporting members 25 each can have an end integrally formed with a respect corner of a bottom surface of the cover 28. Accordingly, the second adhesive 27 should be applied to the corners of the top surface 211 of the carrier 21 to adhere the cover 28 thereto.

In the aforesaid chip package 20 of the digital camera module 10, the carrier 21 defines an open space convenient for movement of a wire bonding tool. Thus, the size of the carrier 21 can be sufficiently minimized to approach the size of the chip 23, and the volume of the chip package 21 and the digital camera module 200 using the package can also be minimized.

In addition, the cover 28 and the first adhesive 26 cooperatively form a relative small sealing space to seal the active area 231 of the chip 23. Thus, the sealing space contains relatively little dust particles therein, the pollution and/or contamination of the active area 231 is reduced and the quality and reliability of the digital camera module 10 is much improved.

Moreover, the inner wall 631 of the seat section 635 of the holder 60 tightly contacts with the peripheral sidewall of the cover 28, thus the holder 61 can be easily and precisely mounted to the chip package 20. Accordingly, the lens module 50 received in the holder 60 can be aligned with the chip 23. Therefore, the quality of the digital camera module 10 can be further improved.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A chip package comprising:
a carrier, the carrier having a top surface and a plurality of top contacts arranged on the top surface;
a chip mounted to the top surface of the carrier, and comprising an active area and a plurality of pads disposed on a top surface thereof;
a plurality of wires electrically respectively connecting one of the pads to a corresponding top contact of the carrier;
an adhesive applied to a peripheral circumference of the top surface of the chip, around the active area;
a cover adhered to the adhesive, the cover and the adhesive cooperatively closing the active area of the chip; and
a supporting member disposed between the top surface of the carrier and the cover to support the cover.

2. The chip package as claimed in claim 1, the top surface of the carrier is approximately planar.

3. The chip package as claimed in claim 2, the supporting member comprises four columns, each column supports a corner of the cover.

4. The chip package as claimed in claim 3, wherein the supporting member is integrally formed with the carrier.

5. The chip package as claimed in claim 4, further comprising a second adhesive applied to the top of the supporting member to adhere the cover to the supporting member.

6. The chip package as claimed in claim 3, wherein the supporting member is integrally formed with the cover.

7. The chip package as claimed in claim 6, further comprising a second adhesive applied to corners of the carrier to adhere the supporting member of the cover to the carrier.

8. The chip package as claimed in claim 1, wherein the first adhesive is further applied to the wires in a manner so as to cover the whole of each wire.

9. The chip package as claimed in claim 1, wherein the first adhesive and the supporting member space a bottom surface of the cover over the wires.

10. A digital camera module comprising:
a chip package comprising:
a carrier, the carrier having a top surface and a plurality of top contacts arranged on the top surface;
a chip mounted to the top surface of the carrier, and comprising an active area and a plurality of pads disposed on a top surface thereof;
a plurality of wires electrically respectively connecting one of the pads to a corresponding top contact of the carrier;
an adhesive applied to a peripheral circumference of the top surface of the chip, around the active area;
a cover adhered to the adhesive, the cover and the adhesive cooperatively closing the active area of the chip; and
a supporting member disposed between the top surface of the carrier and the cover to support the cover; and
a lens module mounted to the chip package.

11. The digital camera module as claimed in claim 10, wherein the supporting member comprises four columns, each column is disposed at a corner of the carrier.

12. The digital camera module as claimed in claim 1, wherein the lens module comprises a holder, which includes a cylinder portion receiving at least one lens therein and a seat portion attached to the chip package.

13. The digital camera module as claimed in claim 12, wherein the seat portion comprises an end surface positioned opposite to the cylinder portion, the end surface has a frame section axially projecting from a periphery thereof, and the end surface is attached to a top surface of the cover, an inner wall of the frame section tightly contacts with a peripheral sidewall of the cover.

14. The digital camera module as claimed in claim 12, wherein the at least one lens is received in a barrel, and the barrel is mounted to the cylinder portion of the holder.

15. A digital camera module comprising:
a base board having a top surface with a plurality of top contacts arranged thereon;
a chip disposed on the top surface, the chip comprising an active area and a plurality of pads disposed thereon;
a plurality of wires respectively electrically connecting one of the pads to a corresponding top contact;
a cover supported above the chip by a supporting member which is securely supported on the top surface of the base board;
an adhesive applied to a periphery of the top surface of the chip around the active area and filled in a gap between the cover and the periphery to cooperatively seal the active area of the chip; and
a holder comprising a seat portion secured to the cover and a lens for forming a focused image on the active area of the chip.

16. The digital camera module as claimed in claim 15, wherein the seat portion comprises a hollow columnar end defining a recess in an inner surface thereof, the cover being received in the recess in such a manner that the columnar end of the seat portion surrounds the cover and tightly contacts with side surfaces of the cover.

17. The digital camera module as claimed in claim 16, wherein the supporting member comprises a plurality of columns arranged on corners of the top surface of the base board, one end of each column being fixed to the base board and the other end of each column being adhered to a bottom surface of the cover by adhesive.
